(19) United States
(12) Patent Application Publication
(10) Pub. No.: US 2024/0304675 A1
(43) Pub. Date: Sep. 12, 2024

(54) COMPOSITE SUBSTRATE, SEMICONDUCTOR STRUCTURE, AND MANFUFACTURING METHOD FOR COMPOSITE SUBSTRATE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/595,013

(22) Filed: Mar. 4, 2024

(30) Foreign Application Priority Data
Mar. 7, 2023 (CN) 202310219058.4

(51) Int. Cl. H01L 29/20; H01L 21/02; H01L 21/265

(52) U.S. Cl. CPC H01L 29/2003; H01L 21/02389; H01L 21/2654

(57) ABSTRACT

Disclosed are a composite substrate, a semiconductor structure, and a manufacturing method for a composite substrate. The composite substrate includes single-crystal AlN; a support substrate disposed below a bottom of the single-crystal AlN; and a transition layer disposed between the single-crystal AlN and the support substrate, where the transition layer includes an oxygen element. In the composite substrate provided by the present disclosure, mechanical strength of the single-crystal AlN may be indirectly improved through a supporting effect performed on the single-crystal AlN by the support substrate located below the bottom of the single-crystal AlN. Meanwhile, the support substrate also plays a role in regulating the stress on the single-crystal AlN, thereby reducing a warping degree of the single-crystal AlN during the subsequent epitaxial process and avoiding the occurrence of cracks or fragments.

### CROSS-REFERENCE TO RELATED APPLICATIONS

The disclosure claims priority to Chinese Patent Application CN202310219058.4, filed on Mar. 7, 2023, the entire contents of which are incorporated herein by reference.

### TECHNICAL FIELD

The present disclosure relates to the field of semiconductor technologies, and in particular, to a composite substrate, a semiconductor structure, and a manufacturing method for the composite substrate.

### BACKGROUND

With the development and application of GaN-based device technologies, the general lighting and luminescence fields in the world are monopolized by GaN-based devices. For lack of GaN single-crystal AlN, a widely-used substrate material for GaN-based LED devices is still Al₂O₃ (sapphire). However, on the one hand, stress is inevitably generated during epitaxy of GaN-based materials on a sapphire substrate, leading to severe warping of an epitaxial wafer, so that a thickness of the substrate needs to be increased to balance the warping. On the other hand, thermal conductivity of the sapphire substrate is poor. As the GaN-based device is being developed towards high-power and small-sized, with greater generation of heat, low thermal conductivity is insufficient to meet development needs, leading to device failure and a significant decrease in lifespan.

### SUMMARY

According to an aspect of the present disclosure, a composite substrate is provided, including: single-crystal AlN; a support substrate disposed below a bottom of the single-crystal AlN; and a transition layer disposed between the single-crystal AlN and the support substrate, where the transition layer includes an oxygen element.

Optionally, a material of the transition layer is an oxide material, and the material of the transition layer includes Al₂O₃ or ZrO₂.

Optionally, a material of the transition layer is a nitride material.

Optionally, the material of the transition layer includes AlON.

Optionally, the transition layer is a periodic structure, and a minimum repeating unit of the periodic structure is an AlON/AlN stacked structure.

Optionally, the support substrate is a polycrystalline material, and a material of the support substrate is any one of an aluminum nitride ceramic substrate, an aluminum oxide ceramic substrate, a silicon carbide ceramic substrate, a boron nitride ceramic substrate, a zirconia ceramic substrate, a magnesium oxide ceramic substrate, a silicon nitride ceramic substrate, and a beryllium oxide ceramic substrate.

Optionally, a surface, away from the support substrate, of the single-crystal AlN is a planar surface or a patterned surface.

Optionally, the composite substrate further includes: a protective layer, where the protective layer at least covers a surface, away from the single-crystal AlN, of the support substrate.

Optionally, the protective layer further covers sidewalls of the single-crystal AlN, the transition layer, and the support substrate.

Optionally, a material of the protective layer includes any one of AlON, SiO₂, and SiN.

Optionally, a surface, away from the support substrate, of the single-crystal AlN is an N-polar surface, or a surface, close to the support substrate, of the single-crystal AlN is the N-polar surface.

Optionally, a thickness of the support substrate is greater than a thickness of the single-crystal AlN.

According to another aspect of the present disclosure, a semiconductor structure is provided, including: a composite substrate according to any one of the composite substrates described above, and an epitaxial structure disposed on the composite substrate, where the semiconductor structure is any one of a high-electron-mobility transistor device, a vertical power device, a radio frequency device, and a light-emitting diode device.

According to another aspect of the present disclosure, a manufacturing method for a composite substrate is provided, including:
providing a sacrificial substrate, and preparing single-crystal AlN on the sacrificial substrate;
providing a support substrate;
preparing a transition layer on a side, away from the sacrificial substrate, of the single-crystal AlN and/or on the support substrate, where the transition layer includes an oxygen element;
bonding the single-crystal AlN onto the support substrate, where the transition layer is disposed between the single-crystal AlN and the support substrate; and
removing the sacrificial substrate.

Optionally, the preparing a transition layer on a side, away from the sacrificial substrate, of the single-crystal AlN and/or on the support substrate includes: depositing the transition layer on the side, away from the sacrificial substrate, of the single-crystal AlN and/or on the support substrate.

Optionally, the preparing a transition layer on a side, away from the sacrificial substrate, of the single-crystal AlN and/or on the support substrate includes: performing ion implantation on the side, away from the sacrificial substrate, of the single-crystal AlN and/or on the support substrate.

Optionally, the preparing a transition layer on a side, away from the sacrificial substrate, of the single-crystal AlN and/or on the support substrate includes: forming a periodic structure on the side, away from the sacrificial substrate, of the single-crystal AlN and/or on the support substrate, where a minimum repeating unit of the periodic structure is an AlON/AlN stacked structure.

Optionally, a surface, away from the support substrate, of the single-crystal AlN is an N-polar surface.

Optionally, after the removing the sacrificial substrate, the manufacturing method further includes: preparing a protective layer on a surface, away from the single-crystal AlN, of the support substrate.

Optionally, after the removing the sacrificial substrate, the manufacturing method further includes: preparing a protective layer on a surface, away from the single-crystal AlN, of the support substrate, and preparing a protective layer on sidewalls of the single-crystal AlN, the transition layer, and the support substrate.

### BRIEF DESCRIPTION OF THE DRAWINGS

FIG. 1 is a schematic structural diagram of a composite substrate according to an embodiment of the present disclosure.

FIG. 2 is a schematic structural diagram of a composite substrate according to another embodiment of the present disclosure.

FIG. 3 is a schematic structural diagram of a composite substrate according to still another embodiment of the present disclosure.

FIG. 4 is a schematic structural diagram of a composite substrate according to yet still another embodiment of the present disclosure.

FIG. 5 is another schematic structural diagram of a composite substrate according to an embodiment of the present disclosure.

FIG. 6a and FIG. 6b are schematic structural diagrams of a composite substrate according to an embodiment of the present disclosure.

FIG. 7a to FIG. 7e are flowcharts of steps of a manufacturing method for a composite substrate according to an embodiment of the present disclosure.

### DETAILED DESCRIPTION OF THE EMBODIMENTS

Exemplary implementation will be illustrated in detail with examples shown in accompanying drawings. When description described below refers to the accompanying drawings, the same numeral in different drawings represents the same or similar elements unless otherwise indicated. The implementation described in the following exemplary implementation does not represent all implementation consistent with the present disclosure. On the contrary, they are only examples of devices that are consistent with some aspects of the present disclosure as detailed in the attached claims.

AlN is a direct bandgap semiconductor material with a wide band gap, and a width of the band gap reaches up to 6.1 eV. AlN is an ideal basic material for preparing deep ultraviolet devices and high voltage power devices. Meanwhile, as a lattice constant mismatch degree between AlN and GaN is only 2.4%, and thermal expansion coefficients thereof are approximately the same, AlN and GaN are ideal substrates for GaN-based epitaxial materials, which can effectively solve a stress problem caused by AlN or GaN epitaxy on sapphire substrates, as well as problems of increased warping and substrate thickness.

However, preparation of AlN single crystal and GaN single-crystal AlN is very complex, so that existing technologies are difficult to prepare large-sized AlN single-crystal AlN and GaN single-crystal AlN. Meanwhile, a preparation cost of small-sized AlN single-crystal AlN and GaN single crystals AlN is high, making it impossible to use them as commercial substrates.

A purpose of the present disclosure is to provide a semiconductor structure to improve quality of epitaxial crystals.

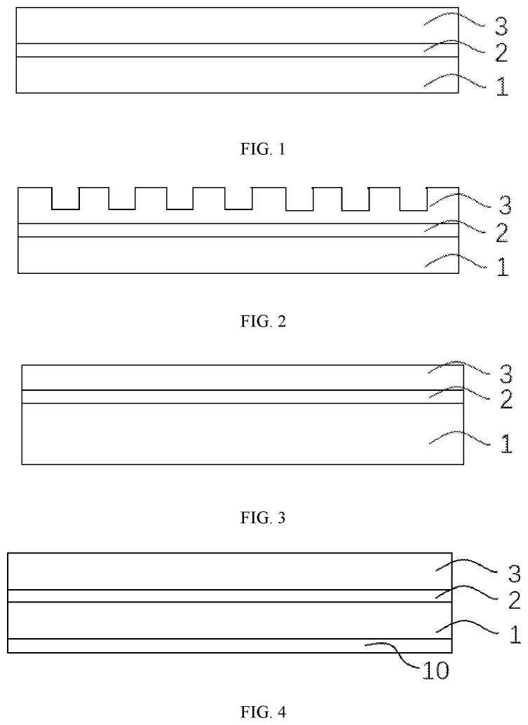

A composite substrate is disclosed by an embodiment of the present disclosure. As shown in FIG. 1, FIG. 1 is a schematic structural diagram of a composite substrate according to an embodiment of the present disclosure. The composite substrate includes: single-crystal AlN 3; a support substrate 1 disposed below a bottom of the single-crystal AlN 3; and a transition layer 2 disposed between the single-crystal AlN 3 and the support substrate 1.

By providing the support substrate 1 below the bottom of the single-crystal AlN 3, mechanical strength of the single-crystal AlN 3 may be indirectly improved through a supporting effect performed on the single-crystal AlN 3 by the support substrate 1. Meanwhile, the support substrate 1 also plays a role in regulating the stress on the single-crystal AlN 3, thereby reducing a warping degree of the single-crystal AlN 3 during the subsequent epitaxial process and avoiding the occurrence of cracks or fragments. Moreover, due to the supporting effect of the support substrate 1 on the single-crystal AlN 3, a thickness of the single-crystal AlN 3 may be reduced, thereby greatly reducing a production cost of the composite substrate. The transition layer 2 is disposed between the support substrate 1 and the single-crystal AlN 3 to increase a bonding force between the single-crystal AlN 3 and the support substrate 1, and release the stress between the single-crystal AlN 3 and the support substrate 1. The arrangement of the transition layer 2 may effectively prevent transfer of dislocations in the support substrate 1 to the single-crystal AlN 3, thereby effectively improving the crystal quality of the single-crystal AlN 3.

Optionally, a crystal lattice of the support substrate 1 matches a crystal lattice of the single-crystal AlN 3. By providing the support substrate 1 and the single-crystal AlN 3 which are lattice matched, the stress between the support substrate 1 and the single-crystal AlN 3 may be effectively reduced, thereby avoiding excessive stress applied by the support substrate 1 on the single-crystal AlN 3, which causes increase of defects in the single-crystal AlN 3, so that the crystal quality of the single-crystal AlN 3 may be ensured.

In this embodiment, a material of the single-crystal AlN 3 includes single-crystal AlN or single crystal GaN. Optionally, the material of the support substrate 1 is a polycrystalline material, and the material of the support substrate 1 is any one of an aluminum nitride ceramic substrate, an aluminum oxide ceramic substrate, a silicon carbide ceramic substrate, a boron nitride ceramic substrate, a zirconia ceramic substrate, a magnesium oxide ceramic substrate, a silicon nitride ceramic substrate, and a beryllium oxide ceramic substrate. Optionally, a material of the transition layer 2 includes an oxygen element. The material of the transition layer 2 may be an oxide material, and the material of the transition layer 2 includes Al₂O₃ or ZrO₂. In this embodiment, the material of the transition layer 2 is a nitride material, and the material of the transition layer 2 includes AlON. With AlON being the material of the transition layer 2, the bonding force between the single-crystal AlN 3 and the support substrate 1 may be increased, and the stress between the single-crystal AlN 3 and the support substrate 1 may be released. Meanwhile, it may be avoided to transfer dislocations in the support substrate 1 to the single-crystal AlN 3, so that the crystal quality of the single-crystal AlN 3 may be effectively improved. In addition, the transition layer 2 of the AlON material may further increase a breakdown voltage of the composite substrate. In other embodiments, the transition layer 2 may also be a periodic structure, and a minimum repeating unit of the periodic structure is an AlON/AlN stacked structure.

In this embodiment, a surface, away from the support substrate 1, of the single-crystal AlN 3 is an N-polar surface; in other optional embodiments, a surface, close to the support substrate 1, of the single-crystal AlN 3 is the N-polar surface, which is not limited to this embodiment.

In this embodiment, hardness of the support substrate 1 is greater than hardness of the single-crystal AlN 3, which further ensures a stress regulation effect of the support substrate 1 on single-crystal AlN 3, so that a high mechanical strength of the semiconductor structure may be further ensured. Optionally, a thickness of the support substrate 1 is greater than a thickness of the single-crystal AlN 3. As a thermal expansion coefficient of the support substrate 1 is less than a thermal expansion coefficient of the single-crystal AlN 3, thermal expansion and warping of the single-crystal AlN 3 during the epitaxial process may be further avoided, which further ensures the quality of the single-crystal AlN 3, and greatly reduces the probability of cracking, so that the crystal quality of the subsequent epitaxial layer may be ensured.

As shown in FIG. 2, FIG. 2 is a schematic structural diagram of a composite substrate according to another embodiment of the present disclosure. The content of this embodiment is roughly the same as that of the embodiment shown in FIG. 1, and a difference is that the surface, away from the support substrate 1, of the single-crystal AlN 3 is a patterned surface, which further reduces the stress between an epitaxial layer formed on the single-crystal AlN 3 and the single-crystal AlN 3, so that the crystal quality of the subsequent epitaxial layer may be ensured.

As shown in FIG. 3, FIG. 3 is a schematic structural diagram of a composite substrate according to still another embodiment of the present disclosure. The content of this embodiment is roughly the same as that of the embodiments shown in FIG. 1 or FIG. 2, and a difference is that a thickness of the support substrate 1 is greater than a thickness of the single-crystal AlN 3, which further improves the mechanical strength of the support substrate 1, so that the stress regulation effect of the support substrate 1 on the single-crystal AlN 3 may be ensured.

As shown in FIG. 4, FIG. 4 is a schematic structural diagram of a composite substrate according to still another embodiment of the present disclosure. The content of this embodiment is roughly the same as that of the embodiments shown in FIG. 1 to FIG. 3, and a difference is that the composite substrate further includes a protective layer 10, where the protective layer 10 at least covers a surface, away from the single-crystal AlN 3, of the support substrate 1. The protective layer 10 has a protective effect on the support substrate 1, and further enhances the mechanical strength of the composite substrate, thereby reducing the possibility of cracks or fragments. In addition, the protective layer 10 and the transition layer 2 apply the same stress on the support substrate 1, which balances the stress and avoids deformation and warping of the support substrate 1.

The material of the protective layer 10 includes any one of AlON, SiO₂, and SiN.

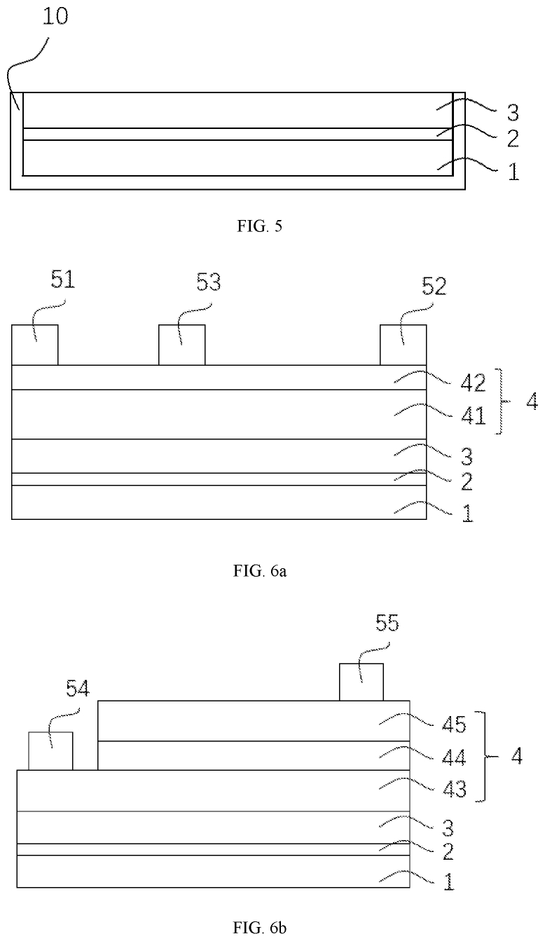

Optionally, as shown in FIG. 5, FIG. 5 is another schematic structural diagram of a composite substrate according to an embodiment of the present disclosure. The protective layer 10 also covers sidewalls of the single-crystal AlN 3, the transition layer 2, and the support substrate 1, which prevents defects on the edge of the single-crystal AlN 3, the transition layer 2, and the support substrate 1 from extending inward during a high-temperature process, so that the crystal quality of the semiconductor layer prepared on the single-crystal AlN 3 during subsequent processes may be ensured. In addition, the protective layer 10 may prevent reactions at the edge of the single-crystal AlN 3 during the subsequent process, so that reliability of the composite substrate may be improved.

An embodiment of the present disclosure provides a semiconductor structure. The semiconductor structure includes: a composite substrate provided by any one of embodiments shown in FIG. 1 to FIG. 3, and an epitaxial structure 4 disposed on the composite substrate. The semiconductor structure provided by this embodiment is any one of a high-electron-mobility transistor device, a vertical power device, a radio frequency device, and a light-emitting diode device.

Specifically, when the semiconductor structure is a high-electron-mobility transistor device, as shown in FIG. 6a, the epitaxial structure 4 includes a channel layer 41 and a barrier layer 42 sequentially formed on the single-crystal AlN 3; and the semiconductor structure further includes a source 51, a drain 52, and a gate 53 disposed on the barrier layer 42.

When the semiconductor structure is a light-emitting diode structure, as shown in FIG. 6b, the epitaxial layer 4 includes a first semiconductor layer 43, a light-emitting layer 44, and a second semiconductor layer 45 sequentially formed on the single-crystal AlN 3, where conductivity types of the first semiconductor layer 43 and the second semiconductor layer 45 are opposite. Optionally, the first semiconductor layer 43 is an N-type semiconductor layer and the second semiconductor layer 45 is a P-type semiconductor layer. And the semiconductor structure further includes a first electrode 54 electrically connected to the first semiconductor layer 43 and a second electrode 55 electrically connected to the second semiconductor layer 45.

Optionally, the epitaxial structure 4 in this embodiment is made of GaN-based materials. GaN is a semiconductor material with a wide band gap, which not only has good stability, high electron drift saturation speed and electron mobility, but also has the characteristics of high electrical breakdown strength, low leakage current, and so on, thereby ensuring electrical performance of the epitaxial structure. In addition, the epitaxial structure 4 of GaN-based materials has extremely low crystal lattice mismatch with the single-crystal AlN 3, thereby effectively reducing the stress caused by lattice mismatch between the epitaxial structure 4 and the composite substrate, and greatly improving the crystal quality of the epitaxial structure 4 and the performance of the semiconductor structure.

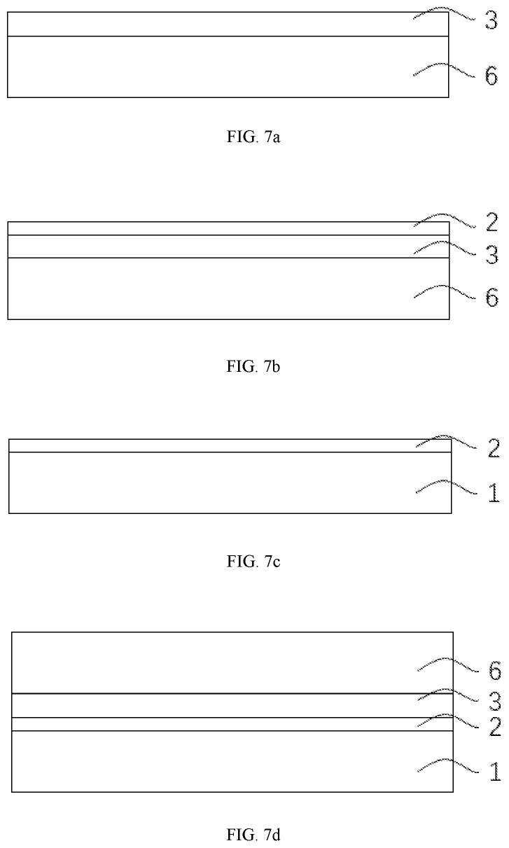

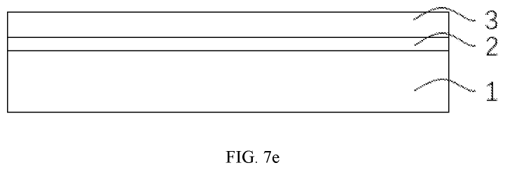

An embodiment of the present disclosure provides a manufacturing method for a composite substrate provided by any one of embodiments shown in FIG. 1 to FIG. 3. As shown in FIG. 7a to FIG. 7e, which are flowcharts of steps of a manufacturing method for a composite substrate according to an embodiment of the present disclosure. The manufacturing method includes: providing a sacrificial substrate 6, and preparing single-crystal AlN 3 on the sacrificial substrate 6; providing a support substrate 1; preparing a transition layer 2 on a side, away from the sacrificial substrate 6, of the single-crystal AlN 3 and/or the support substrate 1, where the transition layer 2 includes an oxygen element; bonding the single-crystal AlN 3 onto the support substrate 1, where the transition layer 2 is disposed between the single-crystal AlN 3 and the support substrate 1; and removing the sacrificial substrate 6.

The transition layer 2 includes an oxygen element. The material of the transition layer 2 may be an oxide material, and the material of the transition layer 2 includes any one of Al₂O₃ and ZrO₂. In this embodiment, the material of the transition layer 2 is a nitride material, and the material of the transition layer 2 includes AlON. With AlON being the material of the transition layer 2, the bonding force between the single-crystal AlN 3 and the support substrate 1 may be increased, and the stress between the single-crystal AlN 3 and the support substrate 1 may be released. Meanwhile, it may be avoided to transfer dislocations in the support substrate 1 to the single-crystal AlN 3, so that the crystal quality of the single-crystal AlN 3 may be effectively improved. In addition, the transition layer 2 of the AlON material may further increase a breakdown voltage of the composite substrate. In other embodiments, the transition layer 2 may also be a periodic structure, and a minimum repeating unit of the periodic structure is an AlON/AlN stacked structure.

Specifically, referring to FIG. 7b to FIG. 7d, in this embodiment, the transition layer 2 may be prepared on the surface, away from the sacrificial substrate 6, of the single-crystal AlN 3, or the transition layer 2 may be prepared on the support substrate 1. The single-crystal AlN 3 is bonded to the support substrate 1 through the transition layer 2. Optionally, the transition layer 2 is formed, through physical vapor deposition (PVD), on the surface, away from the sacrificial substrate 6, of the single-crystal AlN 3 and/or on the support substrate 1; or the transition layer 2 is formed, through ion implantation, on the surface, away from the sacrificial substrate 6, of the single-crystal AlN 3 and/or on the support substrate 1. Optionally, the preparing a transition layer 2 on a side, away from the sacrificial substrate 6, of the single-crystal AlN 3 and/or the support substrate 1 includes: forming a periodic structure on the side, away from the sacrificial substrate 6, of the single-crystal AlN 3 and/or the support substrate 1, where a minimum repeating unit of the periodic structure is an AlON/AlN stacked structure.

A material of the sacrificial substrate 6 includes any one of Si, SiC, Al₂O₃, and SOI. A material of the single-crystal AlN 3 includes any one of single-crystal AlN and single crystal GaN. In this embodiment, a surface, away from the support substrate 1, of the single-crystal AlN 3 is an N-polar surface; in other optional embodiments, a surface, close to the support substrate 1, of the single-crystal AlN 3 is the N-polar surface, which is not limited to this embodiment. A material of the support substrate 1 is a polycrystalline material, and the material of the support substrate 1 is any one of an aluminum nitride ceramic substrate, an aluminum oxide ceramic substrate, a silicon carbide ceramic substrate, a boron nitride ceramic substrate, a zirconia ceramic substrate, a magnesium oxide ceramic substrate, a silicon nitride ceramic substrate, and a beryllium oxide ceramic substrate.

In this embodiment, referring to FIG. 4 and FIG. 5, after the removing the sacrificial substrate 6, the manufacturing method further includes: preparing a protective layer 10 on a surface, away from the single-crystal AlN 3, of the support substrate 1. Optionally, the protective layer 10 may also be prepared on sidewalls of the single-crystal AlN 3, the transition layer 2, and the support substrate 1. A material of the protective layer 10 includes any one of AlON, SiO₂, and SiN.

A composite substrate, a semiconductor structure, and a manufacturing method for the composite substrate provided by the present disclosure have the following beneficial effects.

In the composite substrate provided by the present disclosure, mechanical strength of the single-crystal AlN may be indirectly improved through a supporting effect performed on the single-crystal AlN by the support substrate located below the bottom of the single-crystal AlN. Meanwhile, the support substrate also plays a role in regulating the stress on the single-crystal AlN, thereby reducing a warping degree of the single-crystal AlN during the subsequent epitaxial process and avoiding the occurrence of cracks or fragments.

Through the arrangement of the support substrate, a thickness of the single-crystal AlN may be reduced, thereby greatly reducing production cost of the composite substrate.

A transition layer is disposed between the support substrate and the single-crystal AlN to increase a bonding force between the single-crystal AlN and the support substrate, and release the stress between the single-crystal AlN and the support substrate. The arrangement of the transition layer may effectively prevent transfer of dislocations in the support substrate to the single-crystal AlN, thereby effectively improving the crystal quality of the single-crystal AlN. In addition, the arrangement of the transition layer may further increase a breakdown voltage of the composite substrate.

The semiconductor structure provided by the present disclosure may also effectively reduce the stress caused by crystal lattice mismatch and thermal adaptation between the epitaxial structure and the composite substrate, so that the crystal quality of the epitaxial structure and the performance of the semiconductor structure may be greatly improved.

The implementation described above are only preferred implementation of the present disclosure, and do not impose any formal limitations on the present disclosure. Although the present disclosure has been disclosed in a preferred manner, it is not intended to limit a protection scope of the present disclosure. Any person skilled in the art may make simple modifications, equivalent replacements by using the disclosed technical content within the scope of technical solutions of the present disclosure. And any simple modification, equivalent replacement, or improvement made to the above embodiments based on the technical essence of the present disclosure, which is not separate from the content of the technical solutions of the present disclosure, shall fall into the protection scope of the present disclosure.

What is claimed is:

1. A composite substrate, comprising:
single-crystal AlN;
a support substrate disposed below a bottom of the single-crystal AlN; and
a transition layer disposed between the single-crystal AlN and the support substrate, wherein the transition layer comprises an oxygen element.

2. The composite substrate according to claim 1, wherein a material of the transition layer is an oxide material, and the material of the transition layer comprises Al₂O₃ or ZrO₂.

3. The composite substrate according to claim 1, wherein a material of the transition layer is a nitride material.

4. The composite substrate according to claim 3, wherein the material of the transition layer comprises AlON.

5. The composite substrate according to claim 1, wherein the transition layer is a periodic structure, and a minimum repeating unit of the periodic structure is an AlON/AlN stacked structure.

6. The composite substrate according to claim 1, wherein the support substrate is a polycrystalline material, and a material of the support substrate is any one of an aluminum nitride ceramic substrate, an aluminum oxide ceramic substrate, a silicon carbide ceramic substrate, a boron nitride ceramic substrate, a zirconia ceramic substrate, a magnesium oxide ceramic substrate, a silicon nitride ceramic substrate, and a beryllium oxide ceramic substrate.

7. The composite substrate according to claim 1, wherein a surface, away from the support substrate, of the single-crystal AlN is a planar surface or a patterned surface.

8. The composite substrate according to claim 1, further comprising:
a protective layer, wherein the protective layer at least covers a surface, away from the single-crystal AlN, of the support substrate.

9. The composite substrate according to claim 8, wherein the protective layer further covers sidewalls of the single-crystal AlN, the transition layer, and the support substrate.

10. The composite substrate according to claim 8, wherein a material of the protective layer comprises any one of AlON, SiO₂, and SiN.

11. The composite substrate according to claim 1, wherein a surface, away from the support substrate, of the single-crystal AlN is an N-polar surface, or a surface, close to the support substrate, of the single-crystal AlN is the N-polar surface.

12. The composite substrate according to claim 1, wherein a thickness of the support substrate is greater than a thickness of the single-crystal AlN.

13. A semiconductor structure, comprising:
a composite substrate according to claim 1, and an epitaxial structure disposed on the composite substrate, wherein
the semiconductor structure is any one of a high-electron-mobility transistor device, a vertical power device, a radio frequency device, and a light-emitting diode device.

14. A manufacturing method for a composite substrate, comprising:
providing a sacrificial substrate;
preparing single-crystal AlN on the sacrificial substrate;
providing a support substrate;
preparing a transition layer on a side, away from the sacrificial substrate, of the single-crystal AlN and/or on the support substrate, wherein the transition layer comprises an oxygen element;
bonding the single-crystal AlN onto the support substrate, wherein the transition layer is disposed between the single-crystal AlN and the support substrate; and
removing the sacrificial substrate.

15. The manufacturing method according to claim 14, wherein the preparing a transition layer on a side, away from the sacrificial substrate, of the single-crystal AlN and/or on the support substrate comprises:
depositing the transition layer on the side, away from the sacrificial substrate, of the single-crystal AlN and/or on the support substrate.

16. The manufacturing method according to claim 14, wherein the preparing a transition layer on a side, away from the sacrificial substrate, of the single-crystal AlN and/or on the support substrate comprises:
performing ion implantation on the side, away from the sacrificial substrate, of the single-crystal AlN and/or on the support substrate.

17. The manufacturing method according to claim 14, wherein the preparing a transition layer on a side, away from the sacrificial substrate, of the single-crystal AlN and/or on the support substrate comprises:
forming a periodic structure on the side, away from the sacrificial substrate, of the single-crystal AlN and/or on the support substrate, wherein a minimum repeating unit of the periodic structure is an AlON/AlN stacked structure.

18. The manufacturing method according to claim 14, wherein a surface, away from the support substrate, of the single-crystal AlN is an N-polar surface.

19. The manufacturing method according to claim 14, after the removing the sacrificial substrate, further comprising:
preparing a protective layer on a surface, away from the single-crystal AlN, of the support substrate.

20. The manufacturing method according to claim 14, after the removing the sacrificial substrate, further comprising:
preparing a protective layer on a surface, away from the single-crystal AlN, of the support substrate; and
preparing a protective layer on sidewalls of the single-crystal AlN, the transition layer, and the support substrate.
